(19) United States
(12) Patent Application Publication
(10) Pub. No.: US 2014/0174129 A1
(43) Pub. Date: Jun. 26, 2014

(54) Support Holder For Quartz Dip Stick In Directional Solidification System Furnaces

(71) Applicant: MEMC SINGAPORE,PTE. LTD(UEN200614797D), Singapore (SG)

(72) Inventors: John David Hilker, St. Charles, MO (US); John Gibbons, O'Fallon, MO (US)

(73) Assignee: MEMC SINGAPORE, PTE. LTD (UEN200614797D), Singapore (SG)

(21) Appl. No.: 13/724,091

(22) Filed: Dec. 21, 2012

(51) Int. Cl. C30B 28/06

(52) U.S. Cl. CPC C30B 28/06
USPC 65/29.17; 65/158

(57) ABSTRACT

A support fixture for use in a directional solidification system for the production of multi-crystalline ingots having a housing with a passage that extends into an inner assembly having a crucible includes a collar, an alignment bracket, and an arm. The collar has a mounting structure for attaching the collar to the housing. A passage extends through the collar and defines a longitudinal axis. The alignment bracket is in spaced relation to the collar. The arm extends from the collar to the alignment bracket to support the alignment bracket and prevent movement of the alignment bracket with respect to the collar. The arm is shaped to allow an operator access to an area adjacent to the longitudinal axis.

### FIELD

This disclosure generally relates to directional solidification systems and, more particularly, to an apparatus for measuring the amount of melt in a crucible during the production of multi-crystalline ingots in a directional solidification furnace.

### BACKGROUND

Directional solidification systems include furnaces used in the production of multi-crystalline ingots. During production, raw silicon is loaded into a quartz crucible. The crucible is typically constructed of quartz, or another suitable material that can withstand high temperature while remaining essentially inert. The quartz crucible is supported by graphite support walls that add structural rigidity to the crucible.

After the crucible is charged with the raw silicon, the crucible and the charge are heated to a temperature that is sufficient to melt the silicon. Once the charge has completely melted, it is cooled at a controlled rate to achieve a directional solidification structure.

During this process, a dipstick is typically used to gage the depth of the silicon melt within the crucible. To limit contamination of the silicon melt a rod constructed of an inert material, such as quartz, is used. The quartz rod is brittle and relatively easy to break when the position of the dipstick is being adjusted. If the dipstick is broken, pieces of the dipstick fall into and contaminate the silicon melt. The amount of quartz within the silicon melt cannot be adjusted, which ruins the production run.

Accordingly, there is a need for a supporting apparatus that inhibits the bending and breakage of the quartz dipstick to reduce contamination, and thereby increase run yield and efficiency, resulting in lower operational costs.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

A first aspect is a support fixture for use in a directional solidification system for the production of multi-crystalline ingots having a housing with a passage that extends into an inner assembly having a crucible. The support fixture includes a collar, an alignment bracket, and an arm. The collar has a mounting structure for attaching the collar to the housing, and a passage extending therethrough that defines a longitudinal axis. The alignment bracket is spaced from the collar. The arm extends from the collar to the alignment bracket to support the alignment bracket and prevent movement of the alignment bracket with respect to the collar. The arm is shaped to allow an operator access to an area adjacent to the longitudinal axis.

Another aspect is a system for the production of multi-crystalline ingots. The system includes a base, a lid in spaced relation to the base, a wall extending between the base and the lid to define an inner assembly, and a housing with a passage extending through an opening in the lid. A support fixture has a collar attached to and extending from the housing, an alignment bracket in spaced relation to the collar, and an arm connecting the collar with the alignment bracket to support the alignment bracket and prevent movement of the alignment bracket with respect to the collar. The collar has an upper passage extending therethrough. The upper passage is in coaxial alignment with the passage in the housing. The upper passage defines a longitudinal axis. The arm is shaped to allow an operator access to an area adjacent to the longitudinal axis.

Still another aspect is a method for the production of a multi-crystalline ingot. The method includes providing a system having an inner assembly and a containment vessel with a housing that defines a passage that extends to a crucible located within the inner assembly, placing solid feedstock material in the crucible, melting the solid feedstock material to form a melt, and determining a depth of the melt within the crucible using a rod extending through a support fixture and the housing. The support fixture includes a collar that is attached to and extends from the housing, an alignment bracket that is in spaced relation to the collar, and an arm connecting the collar with the alignment bracket to support the alignment bracket and prevent movement of the alignment bracket with respect to the collar. The collar has an upper passage extending therethrough. The upper passage is in coaxial alignment with the passage and defines a longitudinal axis. The arm is shaped to allow an operator access to an area adjacent to the longitudinal axis.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a partially schematic cross-section of a directional solidification system including a support fixture in accordance with one embodiment;

FIG. 2 is a side elevation of the fixture of FIG. 1;

FIG. 3 is a bottom perspective view of a support fixture in accordance with another embodiment; and

FIG. 4 is a side elevation view of the support fixture in accordance with another embodiment installed on a crystal growing system.

Corresponding reference characters indicate corresponding parts throughout the several views of the drawings.

### DETAILED DESCRIPTION

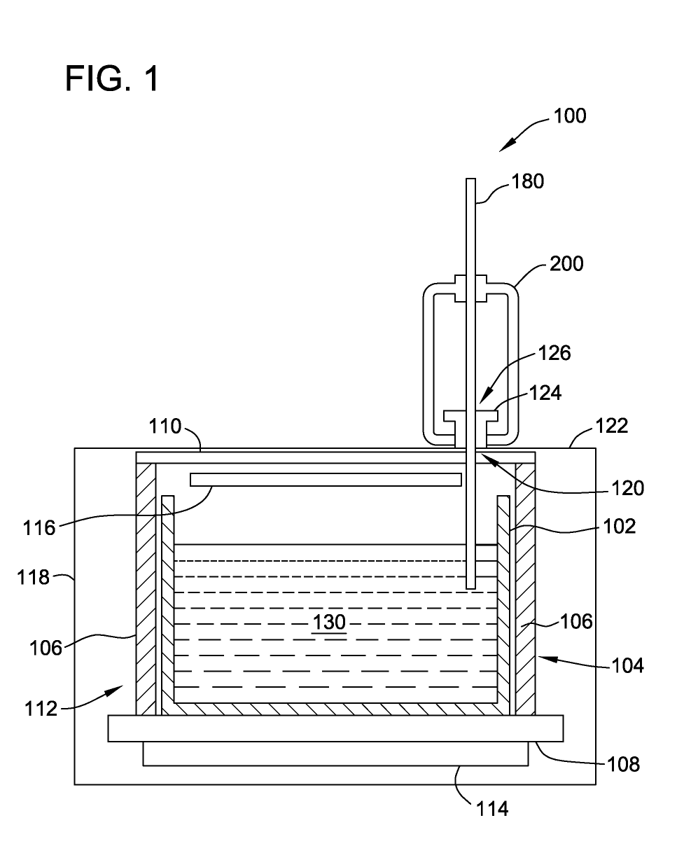

Referring to FIG. 1, a directional solidification system (DSS) for the production of multi-crystalline ingots is shown and indicated generally at 100. The DSS 100 includes a crucible 102 supported by a crucible support 104 including crucible support walls 106, and a crucible base 108. A lid 110 is positioned atop the crucible 102 and spans over the walls 106. Together the crucible 102, the crucible support 104, and the lid 110 form a crucible assembly or an inner assembly 112.

The inner assembly 112 may include a heat exchanger 114 underneath the crucible base 108, and a heater 116 positioned adjacent to the crucible 102. The heater 116 may be a radiant heater that applies the heat necessary to melt the charge of solid feedstock material disposed with the crucible 102 and forming a melt 130 therein. A containment vessel 118 may surround the inner assembly 112, the heat exchanger 114, and the heater 116.

The containment vessel 118 defines an opening 120 through a top portion 122. A housing 124 is located adjacent to the opening 120 and is connected with the containment vessel 118. The housing 124 has a passage 126 that is in communication with the opening 120 in the top portion 122 of the containment vessel 118 and extends down through the lid 110 for the insertion of a dipstick 180 therethrough. The dipstick 180 is typically made of quartz or other suitable material that will not contaminate the melt 130 when inserted therein. The dipstick 180 is used to measure the depth of the melt 130 by being inserted into and then raised from the melt.

In some embodiments, the housing 124 may be connected with the lid 110. In other embodiments, the support fixture may also be constructed in combination with the housing. The support fixture of this embodiment may be attached directly to the housing. In still other embodiments, the support fixture is attached directly to either the lid 110 or containment vessel 118 by an attachment structure.

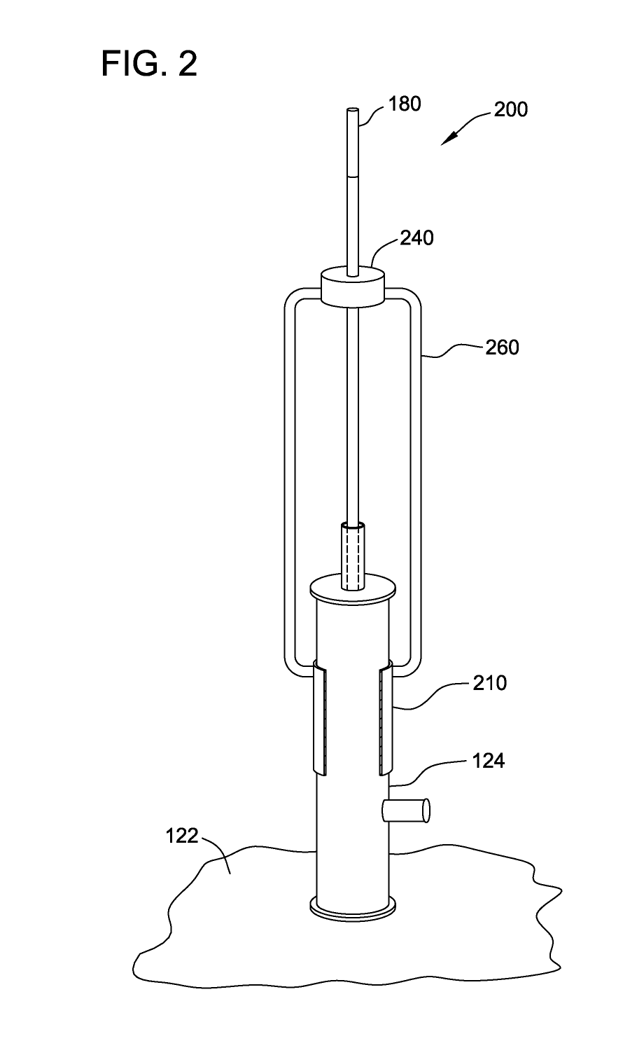

With additional reference to FIG. 2, a support fixture 200 is attached to and extends upward from the housing 124 to provide additional support to the dipstick 180 at a location above the housing. This additional support aids in the prevention of bending and ultimately the breaking of the dipstick 180. The support fixture 200 includes a collar 210, an alignment bracket 240, and an arm 260.

The collar 210 is attached to the housing 190 to provide a stable base for the support fixture 200 in relation to the housing. The collar 210 is generally cylindrical in shape and is fastened about a circumference of the housing 124. The collar 210 may be fastened to the housing 124 by a clamping device or other suitable fastening system.

The alignment bracket 240 includes a body portion 242 and an upwardly extending extension 244. An upper passage 246 extends through both the extension 244 and the body portion 242 of the alignment bracket 240 for accepting a portion of the dipstick 180 therein. The upper passage 246 defines a longitudinal axis extending the length of the support fixture 200. The longitudinal axis is aligned with the passage 126 through the housing 124 to allow for the dipstick 180 to be accepted therethrough.

The alignment bracket 240 is held in spaced relation to the collar 210 by the arm 260 that prevents radial movement of the upper passage 246 with respect to the passage 126 through the housing 124. The alignment bracket 240 may constructed be of any suitable shape and material that provides sufficient additional support to the dipstick 180 and keeps the upper passage from moving with respect to the housing 124.

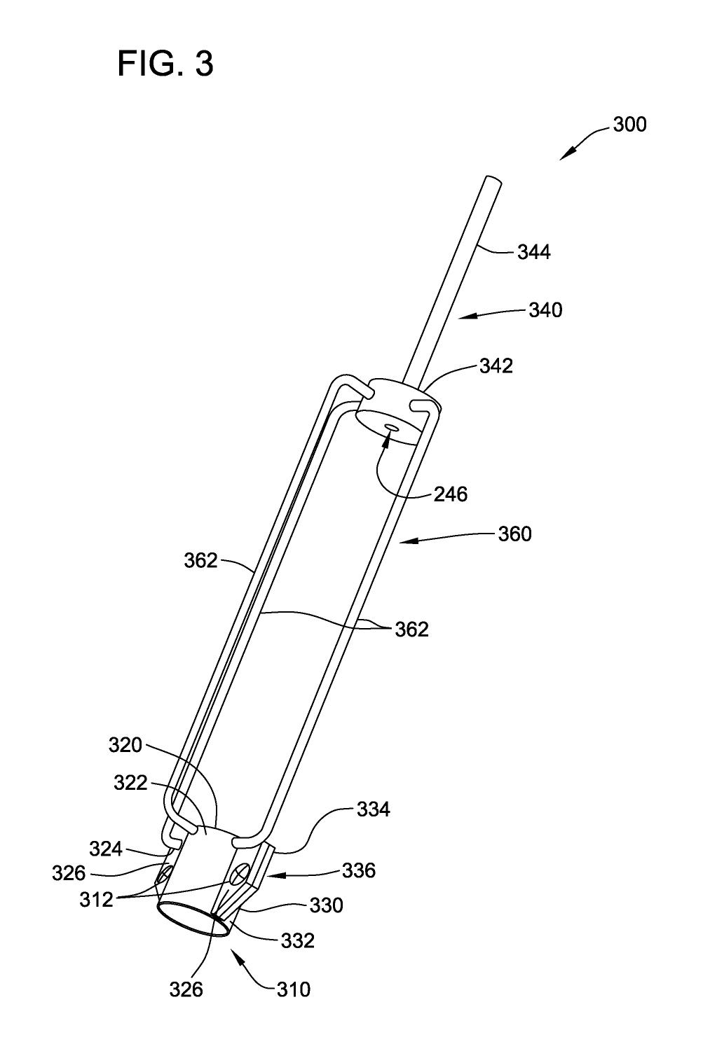

FIG. 3 shows another embodiment of a support fixture 300 for the prevention of bending and breaking of the dipstick 180. Support fixture 300 is discussed only as it differs from the previous embodiment. The support fixture 300 includes a collar 310, an alignment bracket 340 including a body portion 342, and an arm 360 having a plurality of posts 362. The alignment bracket 340 may include an upwardly extending extension 344.

The collar 310 includes a first semi-cylindrical body 320 and a second semi-cylindrical body 330. The first semi-cylindrical body 320 is attached to the plurality of posts 362 about a 180° section of an outer surface 322. Two diametrically opposed tabs 324 extend radially outward from the outer surface 322.

The second semi-cylindrical body 330 includes an outer surface 332 and two diametrically opposed tabs 334 extending radially outward from the outer surface. Each of the tabs 324, 334 include fastening holes 326, 336 extending therethrough for receiving a fastener 312. Each fastening hole 326 in the tabs 324 of the first semi-cylindrical body 320 is aligned with a fastening hole 336 of a tab 334 of the second semi-cylindrical body 330.

During installation of the support fixture 300 onto the housing 124, the first semi-cylindrical body 320 is placed around a portion of the housing. Then the second semi-cylindrical body 330 is placed about an opposed portion of the housing and aligned with the first semi-cylindrical body. Fasteners 312 are then passed through the fastening holes in the tabs of one body portion and at least partially through the tabs of the other body portion.

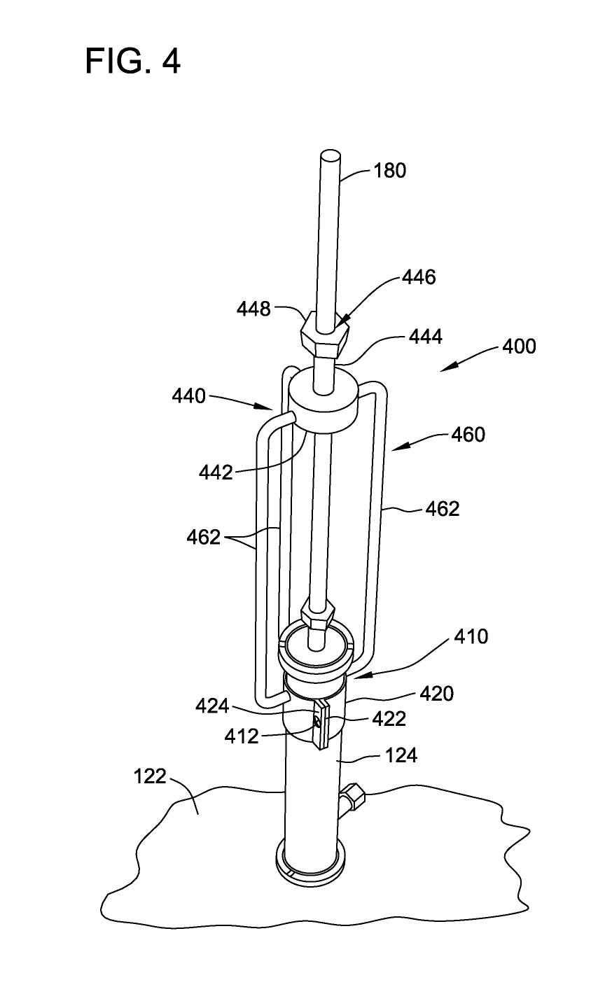

FIG. 4 shows yet another embodiment of a support fixture 400 for the prevention of bending and breakage of the quartz dipstick 180. This embodiment is discussed only as it differs from the previous embodiments. The support fixture 400 includes a collar 410, an alignment bracket 440 in spaced relation to the collar, and an arm 460 having a plurality of posts 462 connected with the collar and the alignment bracket.

The collar 410 includes a cylindrical body 420 with a pair of tabs 422 extending radially outward from the body portion. Each tab 422 has at least one fastener hole 424 for receiving a fastener 412. The fastener holes 424 are in alignment with one another. The collar 410 and posts 462 are flexible enough to allow limited deformation of the collar as the collar is placed about a portion of the housing 124. The fastener 412 is then fed through the hole 424 of one tab 422 and at least partially into the hole 424 of the other tab 422.

Each of the posts 462 are equally spaced about a 180° section of the collar 410 and the alignment bracket 440 to allow access to a dipstick 180 from at least one direction between the housing 124 and the alignment bracket.

The alignment bracket 440 includes a body portion 442 that may have an extension 444 extending upward from the body portion. An upper passage 446 extends through both the extension 444 and the body portion 442 of the alignment bracket 440 for accepting a portion of the dipstick 180 therein. The extension 444 may include a compression fitting 448 for adjusting the diameter of the upper passage 246. Adjustment of the diameter of the upper passage 446 may be used to provide a radial clamping force to the dipstick 180 to prevent longitudinal movement of the dipstick with respect to either the housing 190 or the support fixture 400.

The posts 462 support and align the upper passage 446 through the alignment bracket 440 to prevent radial movement of the upper passage 446 with respect to the passage 192 through the housing 190. Each of the posts 462 are also equally spaced about a 180° section of the alignment bracket 340.

A support fixture consistent with this disclosure prevents bending and breakage of the quartz dipstick. This also prevents pieces of the broken dipstick from falling into the melt and contaminating it. The support fixture also improves the ergonomics for the operator, e.g., the fixture makes the dipstick easier to use. As a result, the yield and efficiency are increased and the overall operational costs are decreased.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the invention, it is intended that all matter contained in the above description and shown in the accompanying drawing[s] shall be interpreted as illustrative and not in a limiting sense.

What is claimed is:

1. A support fixture for use in a directional solidification system for the production of multi-crystalline ingots having a housing with a passage that extends into an inner assembly having a crucible, the support fixture comprising:
a collar having a mounting structure for attaching the collar to the housing, the collar having a passage extending therethrough, the passage defining a longitudinal axis;
an alignment bracket spaced from the collar; and
an arm extending from the collar to the alignment bracket to support the alignment bracket and prevent movement of the alignment bracket with respect to the collar; the arm shaped to allow an operator access to an area adjacent to the longitudinal axis.

2. The support fixture of claim 1, wherein the alignment bracket includes a hole coaxial with the longitudinal axis of the collar for passing a rod therethrough.

3. The support fixture of claim 1, wherein the alignment bracket includes a stabilizing bearing to prevent binding of a rod passing therethrough.

4. The support fixture of claim 1, wherein the arm includes a set of posts spaced radially outward from the longitudinal axis of the collar.

5. The support fixture of claim 4, wherein each of the set of posts extend radially outward and upward from the collar to space each of the set of posts radially outward from the longitudinal axis of the collar.

6. The support fixture of claim 4, wherein each of the set of posts are located along a 180° section of an outer circumference of the collar.

7. The support fixture of claim 1, wherein the mounting structure includes a first portion, a second portion movably connected with the first portion to allow movement of the second portion with respect to the first portion, and a fastening device to prevent the movement of the second portion with respect to the first portion.

8. A system for the production of multi-crystalline ingots, the system comprising:
a base;
a lid being in spaced relation to the base;
a wall extending between the base and the lid to define an inner assembly;
a housing with a passage extending through an opening in the lid; and
a support fixture having:
a collar attached to and extending from the housing; the collar having an upper passage extending therethrough in coaxial alignment with the passage in the housing, the upper passage defining a longitudinal axis;
an alignment bracket in spaced relation to the collar; and
an arm connecting the collar with the alignment bracket to support the alignment bracket and prevent movement of the alignment bracket with respect to the collar; the arm being shaped to allow an operator access to an area adjacent to the longitudinal axis.

9. The system of claim 8, further comprising a crucible located within the inner assembly for containment of a feedstock material.

10. The system of claim 8, further comprising a heater located adjacent to the crucible for supplying heat to the crucible to maintain a melt therein.

11. A method for the production of a multi-crystalline ingot, the method comprising:
providing a system having an inner assembly and a containment vessel with a housing defining a passage therethrough to a crucible located within the inner assembly, and a support fixture located about and extending from the housing; the support fixture including:
a collar attached to and extending from the housing; the collar having an upper passage extending therethrough in coaxial alignment with the passage, the upper passage defining a longitudinal axis;
an alignment bracket in spaced relation to the collar; and
an arm connecting the collar with the alignment bracket to support the alignment bracket and prevent movement of the alignment bracket with respect to the collar; the arm being shaped to allow an operator access to an area adjacent to the longitudinal axis;
placing solid feedstock material in the crucible;
melting the solid feedstock material to form a melt; and
determining a depth of the melt within the crucible using a rod extending through the support fixture and the housing.

12. The method of claim 11, further comprising inserting the rod into the support fixture and then into the housing.

13. The method of claim 11, further comprising moving the rod with respect to both the housing and the support fixture to adjust a location of the rod.

14. The method of claim 11, further comprising placing a heater adjacent to the crucible for melting the solid feedstock material therein.
